(19) United States
(12) Patent Application Publication
(10) Pub. No.: US 2020/0098727 A1
(43) Pub. Date: Mar. 26, 2020

(54) STACKED WIRE-BOND DICE ATTACHED BY PILLARS OR BUMPS ABOVE A FLIP-CHIP DIE ON A SEMICONDUCTOR PACKAGE SUBSTRATE

(71) Applicants: Debendra Mallik, Chandler, AZ (US); Robert L. Sankman, Phoenix, AZ (US); Sanka Ganesan, Chandler, AZ (US); George Vakanas, Tempe, AZ (US); Omkar Karhade, Chandler, AZ (US); Sri Chaitra Jyotsna Chavali, Chandler, AZ (US); Zhaozhi George Li, Chandler, AZ (US); Holly A. Sawyer, Aloha, OR (US)

(72) Inventors: Debendra Mallik, Chandler, AZ (US); Robert L. Sankman, Phoenix, AZ (US); Sanka Ganesan, Chandler, AZ (US); George Vakanas, Tempe, AZ (US); Omkar Karhade, Chandler, AZ (US); Sri Chaitra Jyotsna Chavali, Chandler, AZ (US); Zhaozhi George Li, Chandler, AZ (US); Holly A. Sawyer, Aloha, OR (US)

(21) Appl. No.: 16/141,415

(22) Filed: Sep. 25, 2018

(51) Int. Cl. H01L 25/065; H01L 25/00; H01L 23/00; H01L 23/538

(52) U.S. Cl. CPC H01L 25/0657; H01L 25/50; H01L 24/73; H01L 23/5386; H01L 2224/73253; H01L 2225/06537; H01L 2225/06562; H01L 2225/06582; H01L 2225/06589; H01L 2225/06517

(57) ABSTRACT

A wire-bond memory die is coupled to a system-on-chip processor where the processor is flip-chip mounted on a semiconductor package substrate, and the wire-bond memory die is also flip-chip configured through a redistribution layer that pins out to a series of pillars that contact the semiconductor package substrate. The wire-bond memory die is stacked on the processor and the redistribution layer overhangs the processor to contact the series of pillars.

### FIELD

This disclosure relates to chip-scale packaging (CSP) of stacked semiconductor devices.

### BACKGROUND

Miniaturization of semiconductor device packages, deals with limited available space to interconnect multiple-device systems.

### BRIEF DESCRIPTION OF THE DRAWINGS

Various disclosed embodiments of are illustrated by way of example, and not by way of limitation, in the figures of the accompanying drawings and in which:

FIG. 1A is a cross-section elevation of a semiconductor device 101 during assembly according to an embodiment;

FIG. 1B is a cross-section elevation of the semiconductor device package depicted in FIG. 1A after further processing according to an embodiment;

FIG. 1C is a cross-section elevation of the semiconductor device package depicted in FIG. 1B after further processing according to an embodiment;

FIG. 1D is a cross-section elevation of the semiconductor device package depicted in FIG. 1C after further processing according to an embodiment;

FIG. 1E is a cross-section elevation of the semiconductor device package depicted in FIG. 1D after further processing according to an embodiment;

FIG. 2 is top exploded plan of a semiconductor device package according to an embodiment;

FIG. 3 is a cross-section elevation of a semiconductor device package according to an embodiment;

FIG. 4 is a cross-section elevation of a semiconductor device package according to an embodiment;

FIG. 5 is a perspective elevation of a semiconductor device package according to an embodiment;

FIG. 6 includes computer-illustrated and photo micrographs of pillar structures according to several embodiments;

FIG. 7 is top exploded plan of a semiconductor device package according to an embodiment;

FIG. 8 is a perspective elevation of a semiconductor device package according to an embodiment;

FIG. 9 is a perspective elevation of a semiconductor device package according to an embodiment;

FIG. 10 is a process flow diagram that illustrates a processing embodiment; and

FIG. 11 is included to show an example of a higher-level device application for the pre-packaged stair-stacked memory module with board-mounted components according to several embodiments.

### DETAILED DESCRIPTION

A memory die is flip-chip mounted above a flip-chip system-on-chip processor die. The memory die has wire-bond pads configured for wirebonding. Each of the memory die and the processor die, electrically couples to a semiconductor package substrate; the processor die by direct-bump contact, and the memory die through a fan-in redistribution layer (RDL) and contact pillars that contact the RDL and the semiconductor package substrate. The technology extends to any two useful semiconductor devices that are respectively stacked, and each flip-chip configuration is bonded to the semiconductor package substrate. The stacked semicondcutive device is coupled to the semiconductor package substrate through the RDL.

In an embodiment, the contact pillars include under-bump metallurgy with a copper pillar section and a nickel film that supports a solder bump to contact the RDL. In an embodiment, the under-bump metallurgy assists the copper pillar to remain in place and to achieve a vertical form factor while on a bond pad. The contact pillars complete translation of wire-bond pads, to dense-packed contact with the semiconductor package substrate.

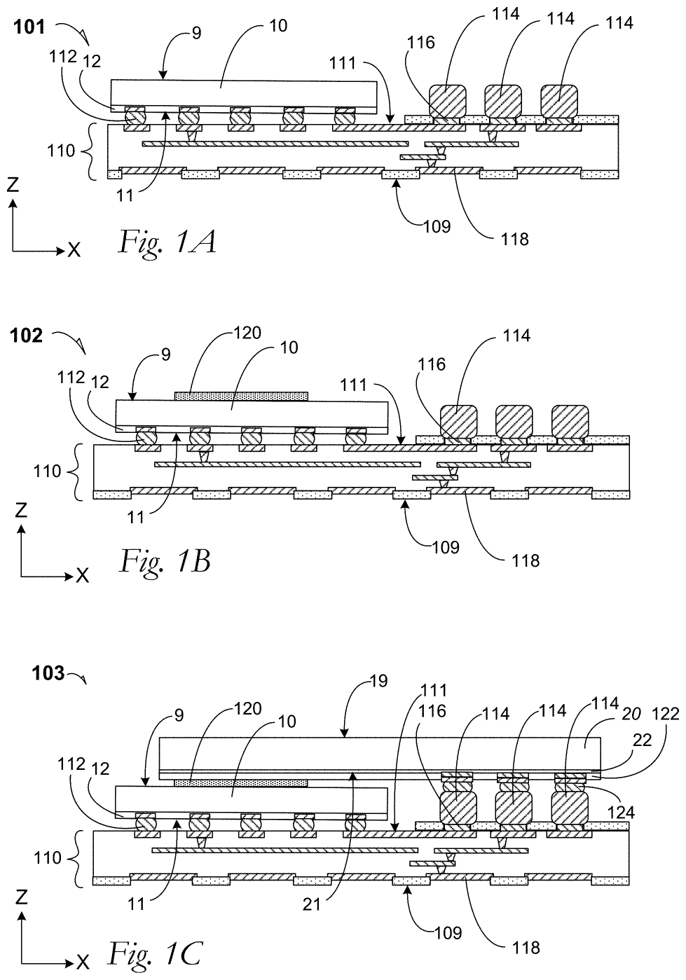

FIG. 1A is a cross-section elevation of a semiconductor device package 101 during assembly according to an embodiment. A first semiconductor device 10 includes an active surface 11 and a backside surface 9. The active surface 11 is a boundary that includes metallization and active devices 12, where the active devices are at the boundary of bulk semiconductor material. The first semiconductor device 10 is flip-chip mounted on a semiconductor package substrate 110 by a ball array (also referred to as an electrical-bump array), one occurrence of which is indicated with reference number 112. The semiconductor package substrate 110 includes a die side 111 and a land side 109.

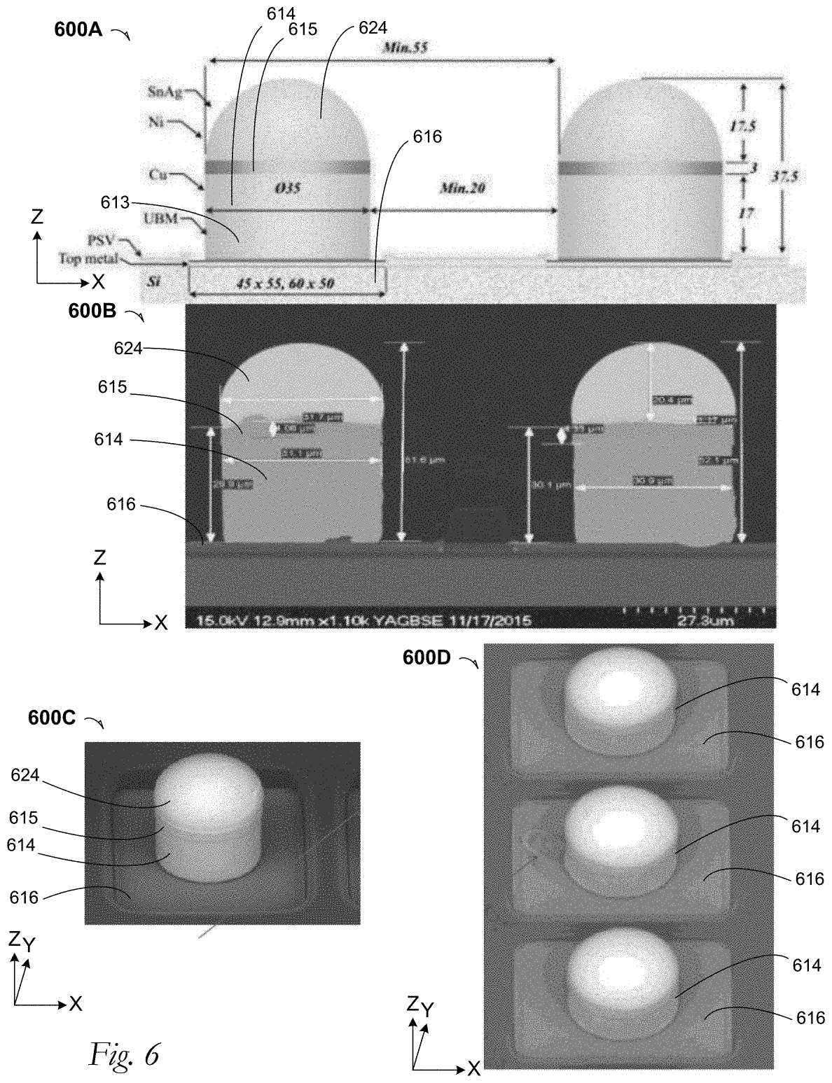

In an embodiment, a pillar 114 contacts a bond pad 116 on the die side 111. The pillar 114 (also referred to as an electrical pillar) includes pillar parts such as under-bump metallurgy, a copper pillar section, a nickel film and a solder bump in an embodiment. Further details of pillar embodiments are described and illustrated in FIG. 6. The land side 109 of the semiconductor package substrate 110 includes landside bond pads, one occurrence of which is indicated with reference number 118. Traces, vias and interlayer dielectrics within the semiconductor package substrate 110 are presented incidentally. Hereinafter, a pillar such as the electrical pillar 114 may be referred to with finer definition as to parts of the pillar, but a “pillar” such as the electrical pillar 114 may be referred to generally, or it may be referred to sequentially with respect to a given semiconductor device with which it couples to the semiconductor package substrate 110.

FIG. 1B is a cross-section elevation of the semiconductor device package 101 depicted in FIG. 1A after further processing according to an embodiment. The semiconductor device package 102 has been processed by forming an adhesive 120 on the backside surface 9 of the first semiconductor device 10. In an embodiment, the adhesive 120 includes dielectric qualities as well as adhesive qualities and a useful Z-thickness to facilitate bonding a stacked die above the backside surface 9 as well as to couple the stacked die to the first semiconductor device 10 through the pillars 114. The adhesive 120 may be referred to generally, or it may be referred to sequentially with respect to a wire-bond die with which it adheres to a sequentially described die.

FIG. 1C is a cross-section elevation of the semiconductor device package 102 depicted in FIG. 1B after further processing according to an embodiment. The semiconductor device package 103 has been processed by seating a subsequent semiconductor device 20 on the adhesive 120 above the backside surface 9 of the first semiconductor device 10. Further, the subsequent semiconductor device 20 includes an active surface 21 and a backside surface 19. The active surface 21 is a boundary that includes metallization and active devices 22, where the active devices are at the boundary of bulk semiconductor material. The subsequent semiconductor device 20 is flip-chip mounted above the first semiconductor device 10 and it is electrically coupled to the semiconductor package substrate 110 by the pillar 114.

Electrical coupling between the subsequent semiconductor device 20 and the semiconductor package substrate 110 is done through a redistribution layer (RDL) 122 according to an embodiment.

Where the subsequent semiconductor device 20 is a memory die that includes wirebond pads arranged around the perimeter of the semiconductor device 20, the RDL 122 translates connection from the perimeter wirebond pads, in part, to the three pillars 114, as well as to other pillars found in the X-Y plane. In an embodiment, the pillar 114 is topped by an electrical bump 124 such as a solder bump 124. In an embodiment, the electrical bump 124 is pre-seated on the RDL 122 in a solder-on-RDL technique.

In an embodiment and above the solder bump 124, a flash layer is part of an RDL bond pad structure. The RDL bond pad structure contacts the metallization and active devices 22 of the subsequent semiconductor device 20.

FIG. 1D is a cross-section elevation of the semiconductor device package 103 depicted in FIG. 1C after further processing according to an embodiment. The semiconductor device package 104 has been processed by forming an overmolding 126 that covers the die side 111 of the semiconductor package substrate 110 as well as the first semiconductor device 10 and the subsequent semiconductor device 20. Underfilling has also occurred where the overmolding 126 has filled between individual bumps of the ball array 112 as well as between the several pillars 114.

FIG. 1E is a cross-section elevation of the semiconductor device package 104 depicted in FIG. 1D after further processing according to an embodiment. The semiconductor device package 105 has been processed by backgrinding the overmolding 126 to form an overmolding backgrinding surface 127 that is about flush with the backside surface 19 of the subsequent semiconductor device 20.

Further processing includes assembling a landside bump array on the land side 109 of the semiconductor package substrate 110, one occurrence of which is indicated with reference number 128.

In an embodiment, a heat sink 130 is above the overmolding backgrinding surface 127 as well as backside surface 19 of the subsequent semiconductor device 20. In an embodiment, the heat sink 130 includes at least one orthogonal fin 131 to lend stiffness to the assembled semiconductor device package 105 where the at least one orthogonal fin 131 can extend into the overmolding 126 without disturbing or contacting other structures such as the first semicondcutive device 10. In an embodiment, several orthogonal fins 131 can be formed and the heat sink as a whole acts as an electromagnetic interference (EMI) sequestering structure to shield a given semiconductor device from EMI noise.

The heat sink 130 is a metal such as heat-sink grade copper or aluminum, and in an embodiment, the adhesive 120 is a thermal grease that assists in heat transmission from the first semiconductor device 10, and through the subsequent semiconductor device 20.

In an embodiment, the semiconductor package substrate 110 is an outer structure at the land side 19 and no land-side bond pads 118 are present. In an embodiment, the semiconductor package substrate 110 is seated on a board 132 such as a motherboard 132 by the land-side bond pads 118, and as indicated by the directional arrows. In an embodiment, the board 132 includes an external shell 134 that acts as at least one of a physical and dielectric protection for the contained semiconductor device package 105, such as where semiconductor device package 105 is a complete system such as an electronic timepiece, or a hand-held computing platform such as a tablet, or a platform such as a wireless telephone.

In an embodiment, any semiconductor device package in this disclosure includes a heat sink such as the heat sink 130. In an embodiment, any semiconductor device package in this disclosure includes an orthogonal fin such as the orthogonal fin 131 of the heat sink 130. In an embodiment, any semiconductor device package in this disclosure includes a board such as the motherboard 132. In an embodiment, any semiconductor device package in this disclosure includes an external shell such as the external shell 134, including where the semiconductor package substrate, such as the semiconductor package substrate 110 has no landside pads on the land side 109.

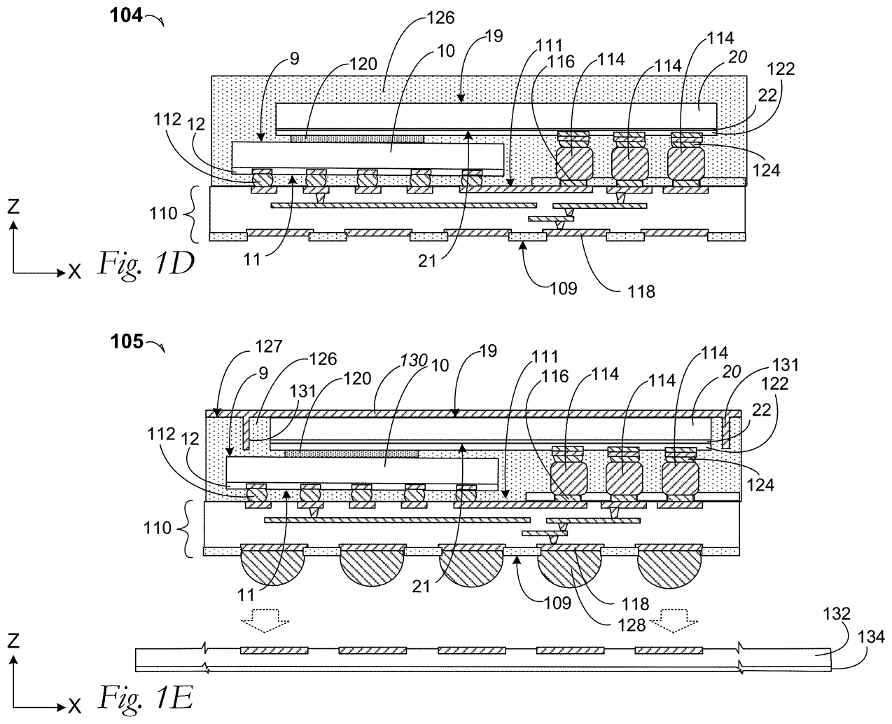

FIG. 2 is top exploded plan of a semiconductor device package 200 according to an embodiment. A semiconductor package substrate 210 accommodates a first semiconductor device 10 similarly as the semiconductor package substrate 110 accommodates the first semiconductor device 10 depicted in FIG. 1. A subsequent semiconductor device 20, such as a wire-bond pad memory die 20 is to be coupled to the first semiconductor device 10 through a redistribution layer 222. The redistribution layer 222 is depicted with a front surface 221 that mates with an adhesive 220 and that couples RDL-to-pillar contacts 223 with the electrical pillars 214.

Whereas the first semiconductor device 10 shows a backside surface 9, the subsequent semiconductor device 20 shows an active surface with metallization 21 and perimeter linear rows of wire-bond pads, one occurrence of which is indicated with reference number 23. In an embodiment and as illustrated, the number of wire-bond bond pads 23, matches a number of pillars 214, and an equal number of RDL-to-pillar contacts 223 on the redistribution layer 222 front surface 221. Where the wire-bond pads 23 are arranged along the perimeter of the subsequent semiconductor device 20, and where the RDL 222 translates connections to the row of RDL-to-pillar contacts 223, the RDL 222 is a fan-in RDL 222.

Incidentally, the reference number 214 touches the pillar 214 that mates with the RDL-to-pillar contact 223, when the RDL 222 is first coupled to the subsequent semiconductor device 20, and then is rotated around the Y-axis and seated at an RDL footprint 225, to couple with the several pillars 214 as well as with the adhesive 220. Similarly, the backside surface (not shown) of the RDL 222 has an equal number of perimeter contacts to accommodate the several wire-bond bond pads 23 on the subsequent semiconductor device 20.

In an embodiment, the RDL 222 includes bond pads with a flash layer that can contact an electrical bump between a given pillar 214 and a matching RDL-to-pillar contact 223.

In an embodiment, the RDL 222 has internal configurations that, for example, allow two or more ground wire-bond pads 23 to be electrically merged and to be coupled to a single RDL-to-pillar contact 223, which lowers overall numbers of RDL-to-pillar contacts 223 and which simplifies matching and coupling all wire-bond pads 23 to pillars 214. In an embodiment, two or more power wire-bond pads 23 are electrically merged within the RDL 222 and are coupled to a single pillar 214.

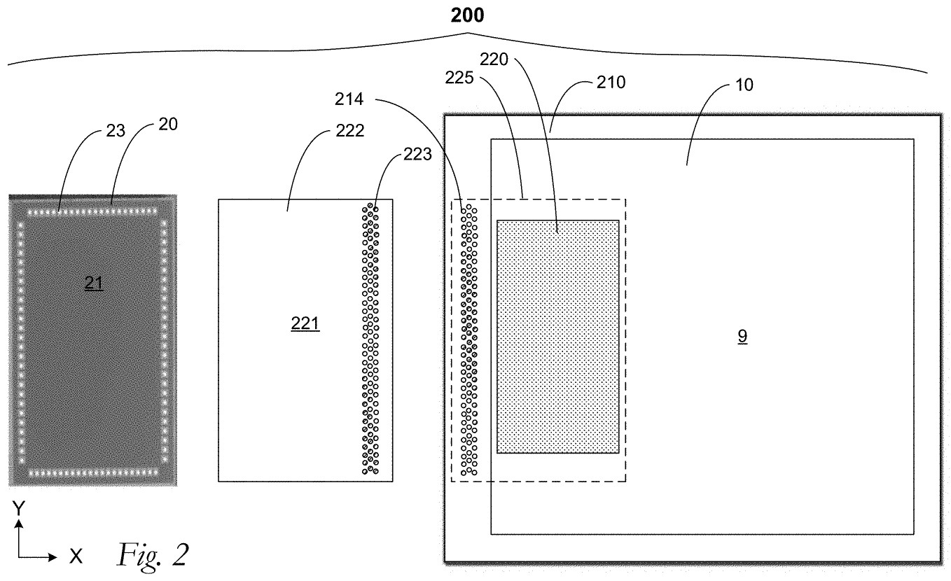

FIG. 3 is a cross-section elevation of a semiconductor device package 300 according to an embodiment. Reference numbers used in FIGS. 1A through 1E are preserved where analogous processing is done, and additional reference numbers describe further processing. In an embodiment, two pillar types 114 and 314 are seated on a semiconductor package substrate 310 on a die side 311, and after seating a subsequent semiconductor device 20 above the first semiconductor device and coupling to the pillars 314, overmolding 326 and back-grinding to expose an overmolding backgrinding surface 327 as well as the subsequent die backside surface 19. Pillar-topped electrical bumps 324 are also exposed through the overmolding back-grinding surface 327. Further processing includes seating an adhesive 320 on the subsequent semiconductor device backside surface 19, and contacting a third die 30 with an active surface 31 that is a boundary for active devices and metallization 32 through an RDL 322 to the electrical pillars 314, and consequently coupling the third semiconductor device 30 to the first semiconductor device 10 through the semiconductor package substrate 310. In an embodiment, the third semiconductor device 30 is a wire-bond pad memory die 30 that interfaces the RDL 322.

In an embodiment, further processing includes forming an upper overmolding (not illustrated) that at least partially encapsulates the third semiconductor device 30 as well as the subsequent semiconductor device backside surface 19.

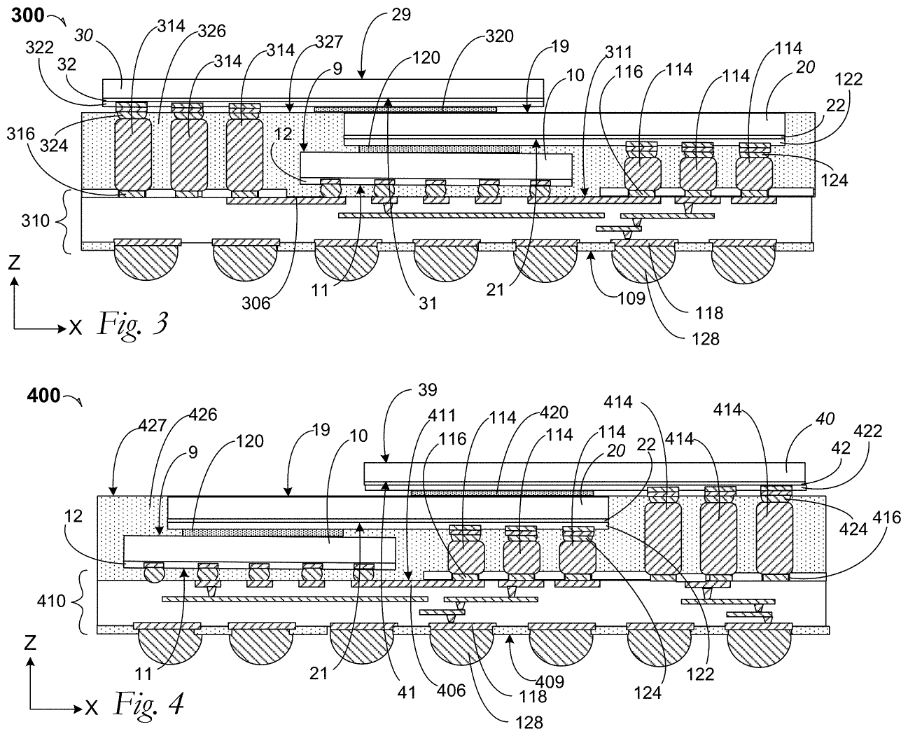

FIG. 4 is a cross-section elevation of a semiconductor device package 400 according to an embodiment. Reference numbers used in FIGS. 1A through 1E are preserved where analogous processing is done, and additional reference numbers describe further processing. In an embodiment, two pillar types 114 and 414 are seated on a semiconductor package substrate 410 on a die side 411, and after seating a subsequent semiconductor device 20 above the first semiconductor device 10 and coupling to the pillars 414, overmolding 426 and back-grinding to expose an overmolding backgrinding surface 427 as well as the subsequent die backside surface 19. Pillar-topped electrical bumps 424 are also exposed through the overmolding back-grinding surface 427. Further processing includes seating an adhesive 420 on the subsequent semiconductor device backside surface 19, and by contacting a third die 40 with an active surface and metallization 42, through an RDL 422 to the pillars 414, and consequently coupling the third semiconductor device 40 to the first semiconductor device 10 through the semiconductor package substrate 410.

In an embodiment, further processing includes forming an upper overmolding (not illustrated) that at least partially encapsulates the third semiconductor device 40 as well as the subsequent semiconductor device backside surface 19.

In an embodiment, combination of architectures in FIGS. 3 and 4 include the third semiconductor device 30 depicted in FIG. 3, side-by-side with the third semiconductor device 40 (in this embodiment, a fourth 40) depicted in FIG. 4, where the semiconductor devices 30 and 40 are side-by-side seated on the subsequent semiconductor device 20, where adhesives 320 and 420 assist to seat the respective semiconductor devices 30 and 40, and where respective pillars 314 and 414 couple the semiconductor devices 30 and 40 to the first semiconductor device 10 through a semiconductor package substrate that is a combination of the semiconductor package substrates 310 and 410, including a trace 306 depicted in FIG. 3 and a trace 406 depicted in FIG. 4.

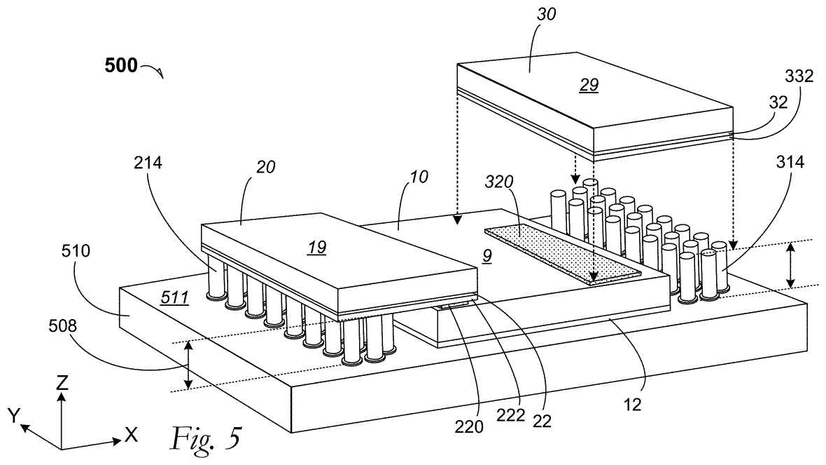

FIG. 5 is a perspective elevation of a semiconductor device package 500 according to an embodiment. Reference numbers used in FIGS. 1A through 1E are preserved where analogous processing is done, and additional reference numbers describe further processing. In an embodiment, two electrical pillar groups 214 and 314 are seated on a semiconductor package substrate 510 on a die side 511, across a first semiconductor device 10 according to an embodiment.

A subsequent semiconductor device 20 is flip-chip bonded by an adhesive 220 to the backside surface 9 of the first semiconductor device 10, and to one grouping of electrical pillars 214, through an RDL 222. The RDL 222 redistributes electrical connection from wire-bond pads (not illustrated) from the subsequent semiconductor device 20, where wire-bond pads are part of active devices and metallization 22 of the subsequent semiconductor device 20. A seated subsequent device height 508 is measured from the semiconductor package substrate die side 511, to the surface of the RDL 222 that contacts the pillars 214. This seated subsequent device height 508 is a distance that is more than the first semiconductor device 10 backside surface 9 is from the semiconductor package substrate die side 511. In an embodiment and included in the seated device height 508, is the electrical pillar 214 and an electrical bump (see bump 124 in FIG. 1A).

In an embodiment, a third semiconductor device 30 is depicted being flip-chip bonded (see the directional arrows at each corner) by a third adhesive 320 to the backside surface 9 of the first semiconductor device 10, and to another grouping of electrical pillars 314, through an RDL 332. The RDL 332 redistributes electrical connection from wire-bond pads (not illustrated) from the third semiconductor device 30, where wire-bond pads are part of active devices and metallization 32 of the third semiconductor device 30.

In an embodiment, the first semiconductor device 10 is an SoC logic processor 10, and the subsequent and third semiconductor devices 20 and 30 are respective wire-bond pad memory devices. In an embodiment, the subsequent and third semiconductor devices 20 and 30 are dynamic random-access memory devices. In an embodiment, the subsequent and third semiconductor devices 20 and 30 are non-volatile random-access memory devices.

In an embodiment, a single stacked semiconductor device takes the space of the subsequent and third semiconductor devices 20 and 30, and the pillars 214 and 314 create a die-straddling form factor (straddling the first semiconductor device 10), where the stacked semiconductor device is larger at least in X-direction than the first semiconductor device 10. In an example embodiment, computational duty is less than data-storage duty such that a physically smaller logic processor 10 is mated to a physically larger memory die, which communicates to the die 10 through the pillars 214 and 314.

FIG. 6 includes computer-illustrated and photo micrographs of electrical pillar structures according to several embodiments.

At 600A, a computer-illustrated pillar structure includes a copper pillar 614 on a bond-wire pad 616, with a nickel film 615 between the copper pillar 614 and an electrical bump 624. In an embodiment, the electrical bump 624 is a tin-silver (SnAg) alloy that exhibits useful adhesion to a nickel (Ni) film 615. In an embodiment, under-bump metallurgy 613 pre-occurs before the copper pillar 614 to assist with an overall achieved vertical height terminating at the electrical bump 624.

At 600B, a photo micrograph illustrates the copper pillar 614 on the bond pad 616, with a nickel film 615 between the copper pillar 614 and an electrical bump 624. In an embodiment, the electrical bump 624 is a tin-silver (SnAg) alloy that exhibits useful adhesion to a nickel (Ni) film 615. In an embodiment, under-bump metallurgy 613 pre-occurs before the copper pillar 614 to assist with an overall achieved vertical height terminating at the electrical bump 624.

At 600C, a perspective photo micrograph view of a pillar 614 (referred to generally) depicts a bond pad 616, the copper pillar 614, the nickel film 615 and the electrical bump 624.

At 600D, a perspective photomicrograph view depicts three pillars 614 on three linearly aligned bond pads 616 of a semiconductor package substrate.

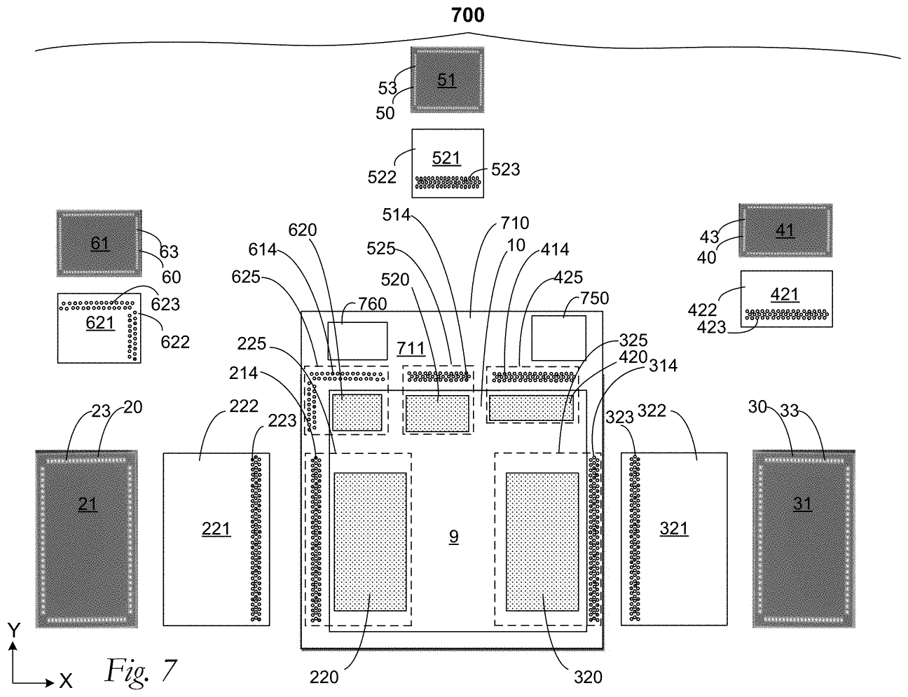

FIG. 7 is top exploded plan of a semiconductor device package 700 according to an embodiment. In this embodiment, more than two semiconductor devices are seated on a first semiconductor device 10 at a backside surface 9, and each semiconductor device is coupled to a semiconductor package substrate 710 through pillars, depending upon a given useful configuration.

In an embodiment, each semiconductor device seated on the first semiconductor device 10, has wire-bond bond pads that are coupled to the pillars through a corresponding RDL. In an embodiment, two or more, but fewer than all of the semiconductor devices, seated on the first semiconductor device 10, have wire-bond bond pads that are coupled to the pillars through a corresponding RDL.

A semiconductor package substrate 710 accommodates the first semiconductor device 10 similarly as the semiconductor package substrate 110 accommodates the first semiconductor device 10 depicted in FIG. 1. A subsequent semiconductor device 20, such as a wire-bond pad memory die 20 is to be coupled to the first semiconductor device 10 through a redistribution layer 122. Similarly, a third semiconductor device 30, such as a wire-bond pad memory die 30 is to be coupled to the first semiconductor device 10 through a redistribution layer 322.

Whereas the first semiconductor device 10 shows the backside surface 9, the subsequent semiconductor device 20 shows an active surface with metallization 21 and perimeter rows of wire-bond pads, one occurrence of which is indicated with numeral 23. In an embodiment and as illustrated, the number of wire-bond bond pads 23, matches a number of first pillars 214, and an equal number of RDL-to-pillar contacts 223 on the redistribution layer 222 front surface 221. Incidentally, the reference number line 214 touches the first pillar 214 that mates with the RDL-to-pillar contact 223, when the RDL 222 is first coupled to the subsequent semiconductor device 20, and then is rotated around the Y-axis and seated at an RDL footprint 225, to couple with the several first pillars 214 as well as an adhesive 220. Similarly, the backside surface (not shown) of the RDL 522 has an equal number of perimeter contacts to accommodate the several wire-bond bond pads 23 on the subsequent semiconductor device 20.

In an embodiment, the RDL 222 has internal configurations that, for example, allow two or more ground wire-bond pad 23 to be electrically merged and to be coupled to a single RDL-to-pillar contact 223, which lowers overall numbers of RDL-to-pillar contacts 223 and which simplifies matching and coupling all wire-bond pads 23 to pillars 214. In an embodiment, two or more power wire-bond pads 23 are electrically merged within the RDL 222 and are coupled to a single electrical pillar 214.

In an embodiment, a third semiconductor device 30 shows an active surface with metallization 31 and perimeter rows of wire-bond pads, one occurrence of which is indicated with numeral 33. In an embodiment and as illustrated, the number of wire-bond bond pads 33, matches a number of electrical pillars 314, and an equal number of RDL-to-pillar contacts 323 on the redistribution layer 322 front surface 321. Incidentally, the reference number line 314 touches the pillar 314 that mates with the RDL-to-pillar contact 323, when the RDL 322 is first coupled to the third semiconductor device 30, and then is rotated around the Y-axis and seated at an RDL footprint 325, to couple with the several third pillars 314 as well as an adhesive 320. Similarly, the backside surface (not shown) of the RDL 322 has an equal number of perimeter contacts to accommodate the several wire-bond bond pads 33 on the third semiconductor device 30.

In an embodiment, the RDL 322 has internal configurations that, for example, allow two or more ground wire-bond pad 33 to be electrically merged and to be coupled to a single RDL-to-pillar contact 323, which lowers overall numbers of RDL-to-pillar contacts 323 and which simplifies matching and coupling all wire-bond pads 33 to pillars 314. In an embodiment, two or more power wire-bond pads 33 are electrically merged within the RDL 322 and are coupled to a single electrical pillar 314.

In an embodiment, a fourth semiconductor device 40 shows an active surface with metallization 41 and perimeter rows of wire-bond pads, one occurrence of which is indicated with numeral 43. In an embodiment, the number of wire-bond bond pads 33, matches a number of fourth pillars 414, and an equal number of RDL-to-pillar contacts 423 on the redistribution layer 422 front surface 421. Incidentally, the reference number line 414 touches the electrical pillar 414 that mates with the RDL-to-pillar contact 423, when the RDL 422 is first coupled to the fourth semiconductor device 40, and then is rotated around the X-axis and seated at an RDL footprint 425, to couple with the several pillars 414 as well as an adhesive 420. Similarly, the backside surface (not shown) of the RDL 422 has an equal number of perimeter contacts to accommodate the several wire-bond bond pads 43 on the fourth semiconductor device 40.

In an embodiment, the RDL 422 has internal configurations that, for example, allow two or more ground wire-bond pad 43 to be electrically merged and to be coupled to a single RDL-to-pillar contact 423, which lowers overall numbers of RDL-to-pillar contacts 423 and which simplifies matching and coupling all wire-bond pads 43 to pillars 414. In an embodiment, two or more power wire-bond pads 43 are electrically merged within the RDL 422 and are coupled to a single electrical pillar 414.

In an embodiment, a fifth semiconductor device 50 shows an active surface with metallization 51 and perimeter rows of wire-bond pads, one occurrence of which is indicated with numeral 53. In an embodiment, the number of wire-bond bond pads 53, matches a number of fifth pillars 514, and an equal number of RDL-to-pillar contacts 523 on the redistribution layer 522 front surface 521. Incidentally, the reference number line 514 touches the electrical pillar 514 that mates with the RDL-to-pillar contact 523, when the RDL 522 is first coupled to the fifth semiconductor device 50, and then is rotated around the X-axis and seated at an RDL footprint 525, to couple with the several electrical pillars 514 as well as an adhesive 520. Similarly, the backside surface (not shown) of the RDL 522 has an equal number of perimeter contacts to accommodate the several wire-bond bond pads 53 on the fifth semiconductor device 50.

In an embodiment, the RDL 522 has internal configurations that, for example, allow two or more ground wire-bond pad 53 to be electrically merged and to be coupled to a single RDL-to-pillar contact 523, which lowers overall numbers of RDL-to-pillar contacts 523 and which simplifies matching and coupling all wire-bond pads 53 to electrical pillars 414. In an embodiment, two or more power wire-bond pads 53 are electrically merged within the RDL 522 and are coupled to a single pillar 514.

In an embodiment, a sixth semiconductor device 60 shows an active surface with metallization 61 and perimeter rows of wire-bond pads, one occurrence of which is indicated with numeral 63. In an embodiment, the number of wire-bond bond pads 63, matches a number of electrical pillars 614, and an equal number of RDL-to-pillar contacts 623 on the redistribution layer 622 front surface 621. In this embodiment, the sixth semiconductor device is configured for corner mounting on the first semiconductor device 10, such that the electrical pillars 614 are arranged in two rows that form a right angle. Where all other disclosed embodiments are represented with three rows of pillars 614, whereas the sixth semiconductor device 60 is corner mounted, which allows for more pillars wrapped at a corner, two rows of pillars 614 indicate fewer layout contacts along a pillar edge of the sixth RDL 622.

In an embodiment, the two rows of pillars 614 are stagger-packed as illustrated. In an embodiment, the two rows of pillars 614 are rectangular-packed. In an embodiment, any of the three-row pillar arrangements are hexagonal closed-packed with a center pillar. In an embodiment, any of the three rows of pillars are rectangular-packed.

Incidentally, the reference number line 614 touches the electrical pillar 614 that mates with the RDL-to-pillar contact 623, when the RDL 622 is first coupled to the sixth semiconductor device 60, and then is rotated around the Y-axis and seated at an RDL footprint 625, to couple with the several pillars 614 as well as an adhesive 620. Similarly, the backside surface (not shown) of the RDL 622 has an equal number of perimeter contacts to accommodate the several wire-bond bond pads 63 on the sixth semiconductor device 60.

In an embodiment, the RDL 622 has internal configurations that, for example, allow two or more ground wire-bond pad 63 to be electrically merged and to be coupled to a single RDL-to-pillar contact 623, which lowers overall numbers of RDL-to-pillar contacts 623 and which simplifies matching and coupling all wire-bond pads 63 to electrical pillars 614. In an embodiment, two or more power wire-bond pads 63 are electrically merged within the RDL 622 and are coupled to a single pillar 614.

In an embodiment, the first semiconductor device 10 is a system-on-chip (SoC) processor such as that made by Intel Corporation of Santa Clara, Calif., and the subsequent and third semiconductor devices 20 and 30 are wire-bond pad memory dice 20 and 30. In an embodiment, the respective fourth, fifth and sixth semiconductor devices 40, 50 and 60 are each different such as a baseband processor, a platform controller hub, and a graphics processor.

In an embodiment, at least one passive-device component 750 and 760 are seated on the semiconductor package substrate 710, such as a resistor, inductor or capacitor. In an embodiment, at least one device 750 or 760 is a motion sensor. In an embodiment, at least one device 750 or 760, is a battery that takes up a larger space across the die side 711 than is depicted. For example, the passive device 750 is the approximate size depicted, or smaller, and the device 760 is a battery that X-Y extends up to passive device 750, while also including the as-depicted area.

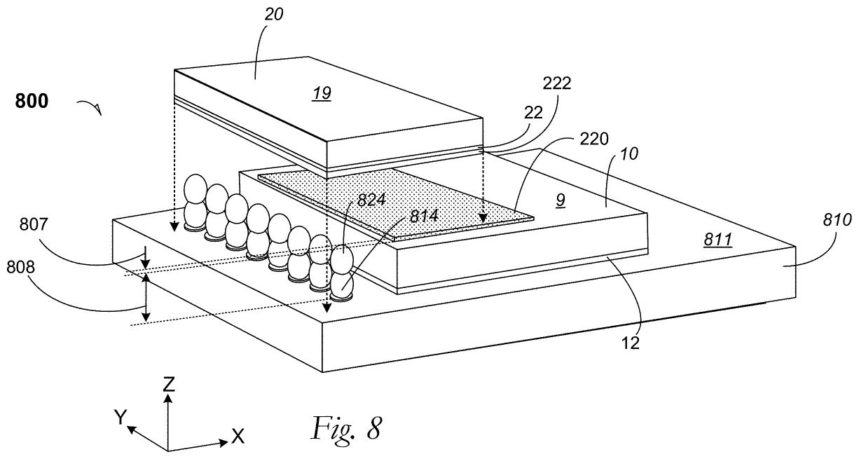

FIG. 8 is a perspective elevation of a semiconductor device package 800 during assembly according to an embodiment. Reference numbers used in FIGS. 1A through 1E are preserved where analogous processing is done, and additional reference numbers describe further processing. In an embodiment, a pillar equivalent of two electrical bumps 824 and 824′ are seated on a semiconductor package substrate 810 on a die side 811, that also supports a flip-chip first semiconductor device 10 according to an embodiment.

A subsequent semiconductor device 20 is being flip-chip bonded by an adhesive 220 to the backside surface 9 of the first semiconductor device 10, and to the several multiple-bump pillars 814 and 824, through an RDL 222. The RDL 222 redistributes electrical connection from wire-bond bond pads (not illustrated) from the subsequent semiconductor device 20, where wire-bond bond pads are part of active devices and metallization 22 of the subsequent semiconductor device 20. A seated subsequent device height 808 is measured from the semiconductor package substrate die side 811, to the surface of the RDL 222 that contacts the pillars 814 and 814′. This seated subsequent device height 808 is a distance that is more than the first semiconductor device 10 backside surface 9 is from the semiconductor package substrate die side 811. During the process of flip-chip seating the subsequent semiconductor device 20 on the bumps 814 and 824 excess bump height 807 is consumed during seating such as by thermal compression bonding (TCB), to leave only the seated subsequent device height 808.

In an embodiment, the electrical bump 814 is seated on the die side 811, and the electrical bump 824 is pre-seated on the RDL 222 in a solder-on-RDL technique.

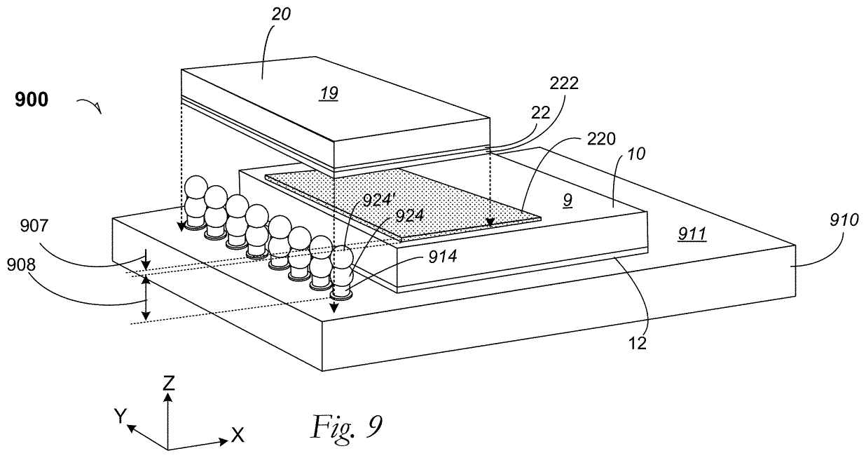

FIG. 9 is a perspective elevation of a semiconductor device package 900 during assembly according to an embodiment. Reference numbers used in FIGS. 1A through 1E are preserved where analogous processing is done, and additional reference numbers describe further processing. In an embodiment, a pillar 914 and an equivalent of two electrical bumps 924 and 924′ are seated on a semiconductor package substrate 910 on a die side 911, that also supports a flip-chip first semiconductor device 10 according to an embodiment.

A subsequent semiconductor device 20 is being flip-chip bonded by an adhesive 220 to the backside surface 9 of the first semiconductor device 10, and to the pillar 914 and the several multiple-bump pillars 924 and 924′, through an RDL 222. The RDL 222 redistributes electrical connection from wire-bond bond pads (not illustrated) from the subsequent semiconductor device 20, where wire-bond bond pads are part of active devices and metallization 22 of the subsequent semiconductor device 20. A seated subsequent device height 908 is measured from the semiconductor package substrate die side 811, to the surface of the RDL 222 that contacts the pillars 914, 924 and 924′. This seated subsequent device height 908 is a distance that is more than the first semiconductor device 10 backside surface 9 is from the semiconductor package substrate die side 9. During the process of flip-chip seating the subsequent semiconductor device 20 on the pillars 914, 924 and 924′ excess bump height 907 is consumed during seating such as by TCB, to leave only the seated subsequent device height 908.

In an embodiment, assembly of a multiple-bump pillars 924 and 924′ is done sequentially by first seating the electrical pillar 914, followed by a solidifying-bump 924 and subsequently a solidifying bump 924′ on the electrical bump 924.

In an embodiment, the electrical bump 924 is seated on the pillar 914, and the electrical bump 924′ is pre-seated on the RDL 222 in a solder-on-RDL technique.

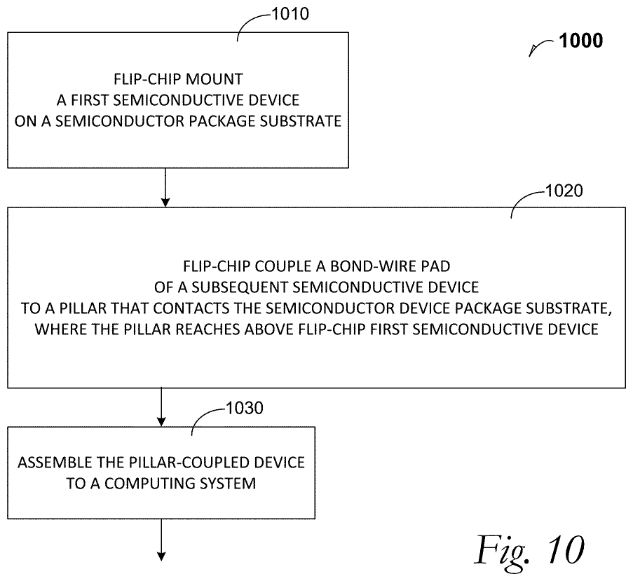

FIG. 10 is a process flow diagram according to several embodiments.

At 1010, the process includes flip-chip mounting a first semiconductor device on a semiconductor package substrate.

At 1020, the process includes flip-chip coupling a bond-wire pad of a subsequent semiconductor device to an electrical pillar that contacts the semiconductor package substrate, where the pillar extends above the flip-chip first semiconductor device.

At 1030, the process includes assembling the first and subsequent semiconductor devices to a computing system.

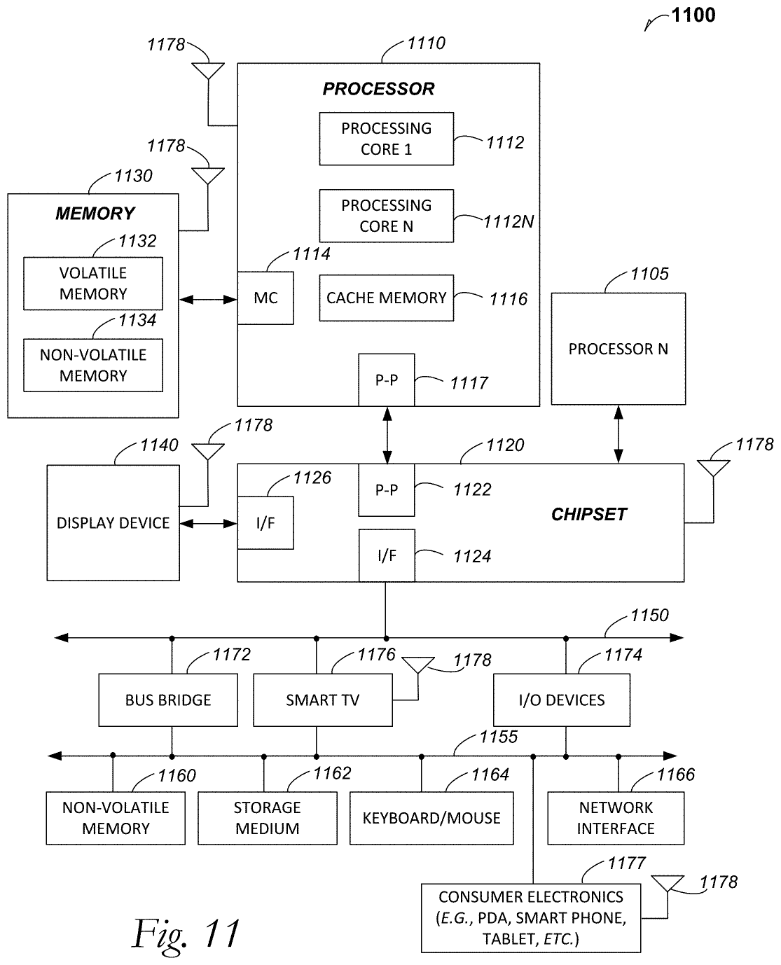

FIG. 11 is a computing system 700 according to an embodiment. FIG. 11 illustrates a system level diagram, according to one embodiment of the invention. For instance, FIG. 11 depicts an example of a microelectronic device that includes a multiple-flip chip, pillar-to bond-wire pad die stack embodiment as described in the present disclosure.

FIG. 11 is included to show an example of a higher level device application for the multiple-flip chip, pillar-to bond-wire pad die stack embodiments. In one embodiment, a system 1100 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance or any other type of computing device. In some embodiments, the multiple-flip chip, pillar-to bond-wire pad die stack embodiment is part of a computing system 1100.

In an embodiment, the processor 1110 has one or more processing cores 1112 and 1112N, where 1112N represents the Nth processor core inside processor 1110 where N is a positive integer. In an embodiment, the electronic device system 1100 using a multiple-flip chip, pillar-to bond-wire pad die stack embodiment includes multiple processors including 1110 and 1105, where the processor 1105 has logic similar or identical to the logic of the processor 1110. In an embodiment, the processing core 1112 includes, but is not limited to, pre-fetch logic to fetch instructions, decode logic to decode the instructions, execution logic to execute instructions and the like. In an embodiment, the processor 1110 has a cache memory 1116 to cache at least one of instructions and data for the multiple-flip chip, pillar-to bond-wire pad die stack-containing computing system 1100. The cache memory 1116 may be organized into a hierarchal structure including one or more levels of cache memory.

In an embodiment, the processor 1110 includes a memory controller 1114, which is operable to perform functions that enable the processor 1110 to access and communicate with memory 1130 that includes at least one of a volatile memory 1132 and a non-volatile memory 1134. In an embodiment, the processor 1110 is coupled with memory 1130 and chipset 1120. The processor 1110 may also be coupled to a wireless antenna 1178 to communicate with any device configured to at least one of transmit and receive wireless signals. In an embodiment, the wireless antenna interface 1178 operates in accordance with, but is not limited to, the IEEE 802.11 standard and its related family, Home Plug AV (HPAV), Ultra Wide Band (UWB), Bluetooth, WiMax, or any form of wireless communication protocol.

In an embodiment, the volatile memory 1132 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. The non-volatile memory 1134 includes, but is not limited to, flash memory, phase change memory (PCM), read-only memory (ROM), electrically erasable programmable read-only memory (EEPROM), or any other type of non-volatile memory device. In an embodiment the multiple-flip chip, pillar-to bond-wire pad die stack is a principal source of non-volatile memory function for the computing system 1100.

The memory 1130 stores information and instructions to be executed by the processor 1110. In an embodiment, the memory 1130 may also store temporary variables or other intermediate information while the processor 1110 is executing instructions. In the illustrated embodiment, the chipset 1120 connects with processor 1110 via Point-to-Point (PtP or P-P) interfaces 1117 and 1122. Either of these PtP embodiments may be achieved using a semiconductor bridge as set forth in this disclosure. The chipset 1120 enables the processor 1110 to connect to other elements in the SiP device system 1100. In an embodiment, interfaces 1117 and 1122 operate in accordance with a PtP communication protocol such as the Intel® QuickPath Interconnect (QPI) or the like. In other embodiments, a different interconnect may be used.

In an embodiment, the chipset 1120 is operable to communicate with the processor 1110, 1105N, the display device 1140, and other devices 1172, 1176, 1174, 1160, 1162, 1164, 1166, 1177, etc. The chipset 1120 may also be coupled to a wireless antenna 1178 to communicate with any device configured to at least do one of transmit and receive wireless signals.

The chipset 1120 connects to the display device 1140 via the interface 1126. The display 1140 may be, for example, a liquid crystal display (LCD), a plasma display, cathode ray tube (CRT) display, or any other form of visual display device. In an embodiment, the processor 1110 and the chipset 1120 are merged into a single SOC such as selected stair-stacked memory module SiP embodiments described herein. Additionally, the chipset 1120 connects to one or more buses 1150 and 1155 that interconnect various elements 1174, 1160, 1162, 1164, and 1166. Buses 1150 and 1155 may be interconnected together via a bus bridge 1172. In an embodiment, the chipset 1120 couples with a non-volatile memory 1160, a mass storage device(s) 1162, a keyboard/mouse 1164, and a network interface 1166 by way of at least one of the interface 1124 and 1104, the smart TV 1176, and the consumer electronics 1177, etc.

In an embodiment, the mass storage device 1162 includes, but is not limited to, a solid state drive, a hard disk drive, a universal serial bus flash memory drive, or any other form of computer data storage medium. In an embodiment, a multiple-flip chip, pillar-to bond-wire pad die stack embodiment is the principal mass-storage device 1162. In one embodiment, network interface 1166 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra Wide Band (UWB), Bluetooth, WiMax, or any form of wireless communication protocol.

While the modules shown in FIG. 11 are depicted as separate blocks within multiple-flip chip, pillar-to bond-wire pad die stack—containing computing system 1100, the functions performed by some of these blocks may be integrated within a single semiconductor circuit or may be implemented using two or more separate integrated circuits. For example, although cache memory 1116 is depicted as a separate block within processor 1110, cache memory 1116 (or selected aspects of 1116) can be incorporated into the processor core 1112.

In an embodiment, either the RDL 50 depicted in FIG. 1 or a substrate bonded to the land ball grid array 90 depicted in FIG. 2, is the outer shell for a hand-held computing system. In an embodiment, the outer shell may be part of a computing system that can be hand held.

Example 1 is a semiconductor device package, comprising: a first semiconductor device, flip-chip electrically contacting a semiconductor package substrate; a subsequent semiconductor device above the first semiconductor device, the subsequent semiconductor device flip-chip electrically coupling to the semiconductor package substrate by an electrical pillar; and a redistribution layer on the subsequent semiconductor device, wherein the redistribution layer couples a bond-wire pad on the subsequent semiconductor device to the electrical pillar.

In Example 2, the subject matter of Example 1 optionally includes wherein the redistribution layer is a fan-in redistribution layer.

In Example 3, the subject matter of any one or more of Examples 1-2 optionally include wherein the pillar is one of a plurality of pillars that correspond to bond-wire pads on the subsequent semiconductor device.

In Example 4, the subject matter of any one or more of Examples 1-3 optionally include wherein the pillar is one of a plurality of pillars that correspond to bond-wire pads on the subsequent semiconductor device, and wherein the subsequent semiconductor device is seated on the first semiconductor device on a backside surface by an adhesive.

In Example 5, the subject matter of any one or more of Examples 1-4 optionally include wherein the pillar is one of a plurality of pillars that correspond to all bond-wire pads on the subsequent semiconductor device, and wherein the plurality of pillars is arranged in one or more rows.

In Example 6, the subject matter of any one or more of Examples 1-5 optionally include wherein the pillar is one of a plurality of pillars that correspond to all bond-wire pads on the subsequent semiconductor device, and wherein the plurality of pillars is arranged in two rows.

In Example 7, the subject matter of any one or more of Examples 1-6 optionally include wherein the pillar is one of a plurality of pillars that correspond to all bond-wire pads on the subsequent semiconductor device, and wherein the plurality of pillars is arranged in three rows.

In Example 8, the subject matter of any one or more of Examples 1-7 optionally include wherein the pillar is topped with an electrical bump that contacts the redistribution layer.

In Example 9, the subject matter of any one or more of Examples 1-8 optionally include wherein the pillar is topped with a first electrical bump, further including a second electrical bump that contacts both the first electrical bump and the redistribution layer.

In Example 10, the subject matter of any one or more of Examples 1-9 optionally include wherein the pillar is one of a plurality of pillars that correspond to bond-wire pads on the subsequent semiconductor device, wherein the subsequent semiconductor device is seated on the first semiconductor device on a backside surface by an adhesive, further including: a third semiconductor device above the first semiconductor device, the third semiconductor device flip-chip electrically coupling to the semiconductor package substrate by an electrical pillar; and a redistribution layer on the third semiconductor device, wherein the redistribution layer couples a bond-wire pad on the third semiconductor device to the electrical pillar.

In Example 11, the subject matter of any one or more of Examples 1-10 optionally include wherein the pillar is one of a plurality of pillars that correspond to bond-wire pads on the subsequent semiconductor device, wherein the subsequent semiconductor device is seated on the first semiconductor device on a backside surface by an adhesive, further including: a third semiconductor device above the first semiconductor device, the third semiconductor device flip-chip electrically coupling to the semiconductor package substrate by an electrical pillar, and wherein the third semiconductor device is seated on the subsequent semiconductor device on a backside surface by an adhesive; and a redistribution layer on the third semiconductor device, wherein the redistribution layer couples a bond-wire pad on the third semiconductor device to the electrical pillar.

In Example 12, the subject matter of any one or more of Examples 1-11 optionally include wherein the pillar is one of a plurality of pillars that correspond to bond-wire pads on the subsequent semiconductor device, wherein the subsequent semiconductor device is seated on the first semiconductor device on a backside surface by an adhesive, further including: a third semiconductor device above the first semiconductor device, the third semiconductor device flip-chip electrically coupling to the semiconductor package substrate by an electrical pillar, and wherein the third semiconductor device is seated on the first semiconductor device on a backside surface by an adhesive; and a redistribution layer on the third semiconductor device, wherein the redistribution layer couples a bond-wire pad on the third semiconductor device to the electrical pillar.

Example 13 is a method of assembling a semiconductor device package, comprising: assembling a subsequent semiconductor device above a flip-chip first semiconductor device, wherein the first semiconductor device is coupled to a semiconductor package substrate; coupling the subsequent semiconductor device to the semiconductor package substrate by an electrical pillar and through a redistribution layer on the subsequent semiconductor device, wherein the electrical pillar contacts the semiconductor package substrate.

In Example 14, the subject matter of Example 13 optionally includes wherein coupling the subsequent semiconductor device to the semiconductor package substrate by an electrical pillar and through the redistribution layer, includes coupling a plurality of electrical pillars through a fan-in redistribution layer.

In Example 15, the subject matter of any one or more of Examples 13-14 optionally include overmolding the first semiconductor device and the subsequent semiconductor device, to cover the pillar; and backgrinding the overmolding to form a backgrinding surface that is about flush with a backside surface of the subsequent semiconductor device.

In Example 16, the subject matter of any one or more of Examples 13-15 optionally include overmolding the first semiconductor device and the subsequent semiconductor device, to cover the pillar; backgrinding the overmolding to form a backgrinding surface that is about flush with a backside surface of the subsequent semiconductor device; and assembling the semiconductor package substrate at a land side to a board.

Example 17 is a computing system, comprising: a system-on-chip (SoC) first semiconductor device, flip-chip electrically contacting a semiconductor package substrate at a die side and through an electrical-bump array; a bond-wire pad containing memory-die subsequent semiconductor device above the SoC first semiconductor device, the subsequent semiconductor device flip-chip electrically contacting a redistribution layer (RDL) at an active surface that includes metallization and active devices; a plurality of electrical pillars coupled to the subsequent semiconductor device, wherein the plurality of electrical pillars is arranged along a side of the SoC first semiconductor device, and wherein the plurality of electrical pillars contacts the semiconductor package substrate; a board contacting the semiconductor package substrate by a landside bump array at a land side; and wherein the SoC die and the memory die are part of a chipset.

In Example 18, the subject matter of Example 17 optionally includes wherein the pillar is one of a plurality of pillars that correspond to bond-wire pads on the memory die, wherein the memory die is seated on the SoC die on a backside surface by an adhesive, further including: a third semiconductor device above the SoC die, the third semiconductor device flip-chip electrically coupling to the semiconductor package substrate by an electrical pillar, and wherein the third semiconductor device is seated on the SoC die on the backside surface by an adhesive; and a redistribution layer on the third semiconductor device, wherein the redistribution layer couples a bond-wire pad on the third semiconductor device to the electrical pillar.

In Example 19, the subject matter of any one or more of Examples 17-18 optionally include wherein the pillar is one of a plurality of pillars that correspond to all bond-wire pads on the subsequent semiconductor device, and wherein the plurality of pillars is arranged in one or more rows.

In Example 20, the subject matter of any one or more of Examples 17-19 optionally include wherein the pillar is one of a plurality of pillars that correspond to all bond-wire pads on the memory die, and wherein the plurality of pillars is arranged in two rows.

In Example 21, the subject matter of any one or more of Examples 17-20 optionally include wherein the pillar is one of a plurality of pillars that correspond to all bond-wire pads on the memory die, and wherein the plurality of pillars is arranged in three rows.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Method examples described herein can be machine or computer-implemented at least in part. Some examples can include a computer-readable medium or machine-readable medium encoded with instructions operable to configure an electrical device to perform methods as described in the above examples. An implementation of such methods can include code, such as microcode, assembly language code, a higher-level language code, or the like. Such code can include computer readable instructions for performing various methods. The code may form portions of computer program products. Further, in an example, the code can be tangibly stored on one or more volatile, non-transitory, or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

1. A semiconductor device package, comprising:
a first semiconductor device, flip-chip electrically contacting a semiconductor package substrate;
a subsequent semiconductor device above the first semiconductor device, the subsequent semiconductor device flip-chip electrically coupling to the semiconductor package substrate by an electrical pillar; and
a redistribution layer on the subsequent semiconductor device, wherein the redistribution layer couples a bond-wire pad on the subsequent semiconductor device to the electrical pillar.

2. The semiconductor device package of claim 1, wherein the redistribution layer is a fan-in redistribution layer.

3. The semiconductor device package of claim 1, wherein the pillar is one of a plurality of pillars that correspond to bond-wire pads on the subsequent semiconductor device.

4. The semiconductor device package of claim 1, wherein the pillar is one of a plurality of pillars that correspond to bond-wire pads on the subsequent semiconductor device, and wherein the subsequent semiconductor device is seated on the first semiconductor device on a backside surface by an adhesive.

5. The semiconductor device package of claim 1, wherein the pillar is one of a plurality of pillars that correspond to all bond-wire pads on the subsequent semiconductor device, and wherein the plurality of pillars is arranged in one or more rows.

6. The semiconductor device package of claim 1, wherein the pillar is one of a plurality of pillars that correspond to all bond-wire pads on the subsequent semiconductor device, and wherein the plurality of pillars is arranged in two rows.

7. The semiconductor device package of claim 1, wherein the pillar is one of a plurality of pillars that correspond to all bond-wire pads on the subsequent semiconductor device, and wherein the plurality of pillars is arranged in three rows.

8. The semiconductor device package of claim 1, wherein the pillar is topped with an electrical bump that contacts the redistribution layer.

9. The semiconductor device package of claim 1, wherein the pillar is topped with a first electrical bump, further including a second electrical bump that contacts both the first electrical bump and the redistribution layer.

10. The semiconductor device package of claim 1, wherein the pillar is one of a plurality of pillars that correspond to bond-wire pads on the subsequent semiconductor device, wherein the subsequent semiconductor device is seated on the first semiconductor device on a backside surface by an adhesive, further including:
a third semiconductor device above the first semiconductor device, the third semiconductor device flip-chip electrically coupling to the semiconductor package substrate by an electrical pillar; and
a redistribution layer on the third semiconductor device, wherein the redistribution layer couples a bond-wire pad on the third semiconductor device to the electrical pillar.

11. The semiconductor device package of claim 1, wherein the pillar is one of a plurality of pillars that correspond to bond-wire pads on the subsequent semiconductor device, wherein the subsequent semiconductor device is seated on the first semiconductor device on a backside surface by an adhesive, further including:
a third semiconductor device above the first semiconductor device, the third semiconductor device flip-chip electrically coupling to the semiconductor package substrate by an electrical pillar, and wherein the third semiconductor device is seated on the subsequent semiconductor device on a backside surface by an adhesive; and
a redistribution layer on the third semiconductor device, wherein the redistribution layer couples a bond-wire pad on the third semiconductor device to the electrical pillar.

12. The semiconductor device package of claim 1, wherein the pillar is one of a plurality of pillars that correspond to bond-wire pads on the subsequent semiconductor device, wherein the subsequent semiconductor device is seated on the first semiconductor device on a backside surface by an adhesive, further including:
a third semiconductor device above the first semiconductor device, the third semiconductor device flip-chip electrically coupling to the semiconductor package substrate by an electrical pillar, and wherein the third semiconductor device is seated on the first semiconductor device on a backside surface by an adhesive; and
a redistribution layer on the third semiconductor device, wherein the redistribution layer couples a bond-wire pad on the third semiconductor device to the electrical pillar.

13. A method of assembling a semiconductor device package, comprising:
assembling a subsequent semiconductor device above a flip-chip first semiconductor device, wherein the first semiconductor device is coupled to a semiconductor package substrate;
coupling the subsequent semiconductor device to the semiconductor package substrate by an electrical pillar and through a redistribution layer on the subsequent semiconductor device, wherein the electrical pillar contacts the semiconductor package substrate.

14. The method of claim 13, wherein coupling the subsequent semiconductor device to the semiconductor package substrate by an electrical pillar and through the redistribution layer, includes coupling a plurality of electrical pillars through a fan-in redistribution layer.

15. The method of claim 13, further including:
overmolding the first semiconductor device and the subsequent semiconductor device, to cover the pillar; and
backgrinding the overmolding to form a backgrinding surface that is about flush with a backside surface of the subsequent semiconductor device.

16. The method of claim 13, further including:
overmolding the first semiconductor device and the subsequent semiconductor device, to cover the pillar;
backgrinding the overmolding to form a backgrinding surface that is about flush with a backside surface of the subsequent semiconductor device; and
assembling the semiconductor package substrate at a land side to a board.

17. A computing system, comprising:
a system-on-chip (SoC) first semiconductor device, flip-chip electrically contacting a semiconductor package substrate at a die side and through an electrical-bump array;
a bond-wire pad containing memory-die subsequent semiconductor device above the SoC first semiconductor device, the subsequent semiconductor device flip-chip electrically contacting a redistribution layer (RDL) at an active surface that includes metallization and active devices;
a plurality of electrical pillars coupled to the subsequent semiconductor device, wherein the plurality of electrical pillars is arranged along a side of the SoC first semiconductor device, and wherein the plurality of electrical pillars contacts the semiconductor package substrate;
a board contacting the semiconductor package substrate by a landside bump array at a land side; and
wherein the SoC die and the memory die are part of a chipset.

18. The computing system of claim 17, wherein the pillar is one of a plurality of pillars that correspond to bond-wire pads on the memory die, wherein the memory die is seated on the SoC die on a backside surface by an adhesive, further including:
a third semiconductor device above the SoC die, the third semiconductor device flip-chip electrically coupling to the semiconductor package substrate by an electrical pillar, and wherein the third semiconductor device is seated on the SoC die on the backside surface by an adhesive; and
a redistribution layer on the third semiconductor device, wherein the redistribution layer couples a bond-wire pad on the third semiconductor device to the electrical pillar.

19. The computing system of claim 17, wherein the pillar is one of a plurality of pillars that correspond to all bond-wire pads on the subsequent semiconductor device, and wherein the plurality of pillars is arranged in one or more rows.

20. The computing system of claim 17, wherein the pillar is one of a plurality of pillars that correspond to all bond-wire pads on the memory die, and wherein the plurality of pillars is arranged in two rows.

21. The computing system of claim 17, wherein the pillar is one of a plurality of pillars that correspond to all bond-wire pads on the memory die, and wherein the plurality of pillars is arranged in three rows.
